(19) United States
(12) Patent Application Publication
(10) Pub. No.: US 2020/0168477 A1
(43) Pub. Date: May 28, 2020

(54) METHODS OF FABRICATING SEMICONDUCTOR PACKAGE

(71) Applicant: Lbsemicon Inc., Pyeongtaek-si (KR)

(72) Inventors: Jae Jin Kwon, Hwaseong-si (KR); Jin Kuk Lee, Hwaseong-si (KR)

(73) Assignee: Lbsemicon Inc., Pyeongtaek-si (KR)

(21) Appl. No.: 16/693,300

(22) Filed: Nov. 24, 2019

(30) Foreign Application Priority Data
Nov. 26, 2018 (KR) 10-2018-0147089

(51) Int. Cl. H01L 21/56; H01L 23/00; H01L 21/683

(52) U.S. Cl. CPC H01L 21/568; H01L 21/561; H01L 24/03; H01L 24/11; H01L 24/05; H01L 2221/68309; H01L 21/6835; H01L 2224/02381; H01L 2224/0401; H01L 2224/05569; H01L 2224/13024; H01L 24/13

(57) ABSTRACT

Disclosed is a method of fabricating a semiconductor package, the method including forming a first resin material, in which alignment grooves are formed, on a carrier substrate; respectively aligning semiconductor chips, to which posts are respectively attached, in the alignment grooves; forming a second resin material on the carrier substrate, the semiconductor chips, and the posts; grinding a portion of the second resin material such that portions of the posts are exposed; respectively forming redistribution layers on the exposed posts; respectively forming insulating film patterns or UBM patterns on the redistribution layers; respectively bonding solder balls onto the redistribution layers or the UBM patterns; removing the carrier substrate from the first resin material and the semiconductor chips; and sawing the first resin material and the second resin material to separate into individual chips.

### RELATED APPLICATION

This application claims the benefit of priority of Korean Patent Application No. 10-2018-0147089 filed on Nov. 26, 2018, the contents of which are incorporated herein by reference in their entirety.

### FIELD AND BACKGROUND OF THE INVENTION

The present disclosure relates to a method of fabricating a semiconductor package, and more particularly to a method of fabricating a fan-out wafer-level package. The trend in today's electronics industry is to make products that are lighter, smaller, faster, more versatile, more powerful and more reliable at low cost. One of the important technologies that enable the realization of such a product design is package technology, and thus a chip-scale package (CSP) has recently been developed. A chip-scale package is a miniaturized semiconductor package having a semiconductor chip size. Although such a chip-scale package has a significant advantage in terms of size, it still has many drawbacks compared to existing plastic packages. Particularly, a chip-scale package is disadvantageous in that it is difficult to secure reliability, a lot of manufacturing equipment and raw materials are required to fabricate a chip-scale package, and price competitiveness is low due to high manufacturing cost. As a solution to such problems, a wafer-level chip-scale package has attracted attention. When a semiconductor wafer is fabricated according to a general wafer fabrication process, individual chips are separated from the wafer and subjected to a package assembly process. Although the package assembly process requires equipment and raw materials different from those of a wafer fabrication process, thus being a completely different process therefrom, it is possible to fabricate a package as a complete product at a wafer level, i.e., in a state in which individual chips are not separated from a wafer. In addition, existing wafer manufacturing equipment and processes may be used as manufacturing equipment or processes for fabricating the package. Accordingly, the use of raw materials additionally used to fabricate a package can be minimized.

As a form of such a wafer-level package, a fan wherein terminals and wiring are typically formed inside a chip has been developed.

In a process of fabricating an existing fan, a wafer-level package, the sizes of solder balls and a pitch between the solder balls are simultaneously decreased when the size of a chip is decreased. Accordingly, excessively small solder balls may cause a decrease in bonding strength, and too small pitch between the solder balls may cause a poor contact of a bridge between the solder balls. In addition, there is an inconvenience that a layout should be changed according to the size of a chip.

To address such inconvenience, a fan-out wafer-level package has been developed. In the case of the fan-out wafer-level package, I/O terminals and wiring may be disposed also in an epoxy molding compound (EMC) region on an outer side of a semiconductor chip, so that the aforementioned defects due to solder ball sizes and a pitch therebetween may be reduced, and a standardized ball layout may be used even when the size of a semiconductor chip is changed. In addition, it is possible to implement a system in package, wherein several chips are mounted in one package, and to package chips with many I/O terminals.

As a related art document, there is Korean Patent Application Publication No. 2011-011913 (published on Nov. 2, 2011, entitled “apparatus for manufacturing fan-out-type wafer-level package”).

### SUMMARY OF THE INVENTION

Therefore, the present disclosure has been made in view of the above problems, and it is one object of the present disclosure to provide a method of fabricating a semiconductor package which is capable of facilitating the alignment of semiconductor chips of a fan-out wafer-level package. However, this is only for illustrative purposes, and the scope of the present disclosure is not limited thereto.

In accordance with an aspect of the present disclosure, the above and other objects can be accomplished by the provision of a method of fabricating a semiconductor package, the method including: forming a first resin material, in which alignment grooves are formed, on a carrier substrate; respectively aligning semiconductor chips, to which posts are respectively attached, in the alignment grooves; forming a second resin material on the carrier substrate, the semiconductor chips, and the posts; grinding a portion of the second resin material such that portions of the posts are exposed; respectively forming redistribution layers on the exposed posts; respectively forming insulating film patterns or UBM patterns on the redistribution layers; respectively bonding solder balls onto the redistribution layers or the UBM patterns; removing the carrier substrate from the first resin material and the semiconductor chips; and sawing the first resin material and the second resin material to separate into individual chips.

In addition, in accordance with the present disclosure, the respectively aligning may include respectively forming the adhesive layers on lower surfaces of the semiconductor chips; and aligning the semiconductor chips in a face-up shape wherein the adhesive layers on lower surfaces of the semiconductor chips are bonded to the carrier substrate and upper surfaces of the semiconductor chips are active surfaces.

In addition, in accordance with the present disclosure, the forming of the first resin material may include printing or molding the first resin material on the carrier substrate; and removing portions of the first resin material to form the alignment grooves on the carrier substrate.

In addition, in accordance with the present disclosure, the removing may include processing the first resin material using one or more selected from among etching, sawing, drilling, laser drilling, through mold via (TMV) processing, and a combination thereof such that portions of the carrier substrate are exposed.

In addition, in accordance with the present disclosure, the forming of the first resin material may include inserting the carrier substrate into an insert mold to form cavities and insert-molding the first resin material around the cavities, so as to form the alignment grooves in the first resin material.

In addition, in accordance with the present disclosure, the forming of the first resin material may include separately fabricating the first resin material, in which the alignment grooves are formed, using a mold; and attaching the first resin material to the carrier substrate.

In addition, in accordance with the present disclosure, the semiconductor package may be a fan-out wafer-level package.

In addition, in accordance with the present disclosure, the forming of the first resin material may include forming the alignment grooves in the first resin material to be larger than the semiconductor chips and forming the first resin material to be thicker than the semiconductor chips.

In addition, in accordance with the present disclosure, the forming of the second resin material may include forming the second resin material with substantially the same material as the first resin material.

In accordance with another aspect of the present disclosure, there is provided a method of fabricating a semiconductor package, the method including: forming a temporary adhesive layer on a carrier substrate; forming a first resin material, in which alignment grooves are formed, on the temporary adhesive layer; respectively aligning semiconductor chips in the alignment grooves; forming a second resin material on the carrier substrate and the semiconductor chips; removing the temporary adhesive layer and the carrier substrate from the semiconductor chips and the second resin material, and reversing the semiconductor chips and the second resin material such that the semiconductor chips are exposed upward; respectively forming redistribution layers on the exposed semiconductor chips; respectively forming insulating film patterns or UBM patterns on the redistribution layers; respectively bonding solder balls onto the redistribution layers or the UBM patterns; and sawing the first resin material and the second resin material to separate into individual chips.

In addition, in accordance with the present disclosure, the respectively aligning may include aligning the semiconductor chips in a face-down shape wherein lower surfaces of the semiconductor chips become active surfaces.

In addition, in accordance with the present disclosure, the forming of the first resin material may include printing or molding the first resin material on the temporary adhesive layer; and removing portions of the first resin material to form the alignment grooves on the temporary adhesive layer.

In addition, in accordance with the present disclosure, the removing may include processing the first resin material using one or more selected from among etching, sawing, drilling, laser drilling, through mold via (TMV) processing, and a combination thereof such that portions of the temporary adhesive layer are exposed.

In addition, in accordance with the present disclosure, the forming of the first resin material may include inserting the temporary adhesive layer and the carrier substrate into an insert mold to form cavities and insert-molding the first resin material around the cavities, so as to form the alignment grooves in the first resin material.

In addition, in accordance with the present disclosure, the forming of the first resin material may include separately fabricating the first resin material, in which the alignment grooves are formed, using a mold; and attaching the first resin material to the temporary adhesive layer.

In addition, in accordance with the present disclosure, the semiconductor package may be a fan-out wafer-level package.

In addition, in accordance with the present disclosure, the forming of the first resin material may include forming the alignment grooves in the first resin material to be larger than the semiconductor chips and forming the first resin material to be thicker than the semiconductor chips.

In addition, in accordance with the present disclosure, the forming of the second resin material may include forming the second resin material with substantially the same material as the first resin material.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 illustrates a sectional view of a semiconductor package according to an embodiment of the present disclosure;

FIGS. 2, 3, 4, 5, 6, 7, 8 and 9 are sectional views illustrating a process of fabricating the semiconductor package of FIG. 1 step by step;

FIG. 10 is a flowchart illustrating a method of fabricating the semiconductor package of FIG. 1;

FIG. 11 is a flowchart illustrating an embodiment of the method of fabricating a semiconductor package of FIG. 10;

FIG. 12 is a flowchart illustrating another embodiment of the method of fabricating a semiconductor package of FIG. 10;

FIG. 13 is a flowchart illustrating still another embodiment of the method of fabricating a semiconductor package of FIG. 10;

FIG. 14 illustrates a sectional view of a semiconductor package according to another embodiment of the present disclosure;

FIGS. 15, 16, 17, 18, 19, 20 and 21 are sectional views illustrating a process of fabricating the semiconductor package of FIG. 14 step by step; and

FIG. 22 is a flowchart illustrating a method of fabricating the semiconductor package of FIG. 14.

### DESCRIPTION OF SPECIFIC EMBODIMENTS OF THE INVENTION

Hereinafter, exemplary embodiments of the present disclosure will be described more fully with reference to the accompanying drawings. However, the present disclosure may be embodied in many different forms and should not be construed as limited to the embodiments set forth herein. Rather, these embodiments are provided so that this disclosure will be thorough and complete, and will fully convey the scope of the disclosure to those skilled in the art. For descriptive convenience, the sizes of constituents may be exaggerated or reduced in the drawings.

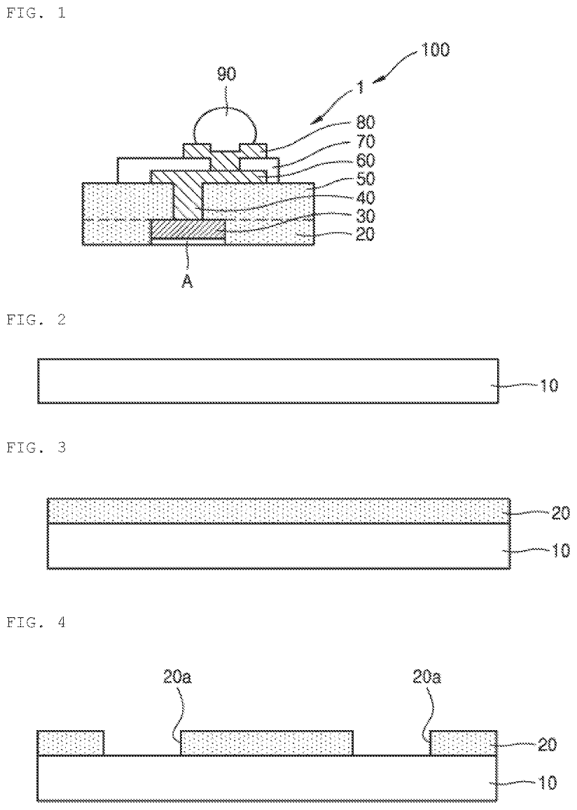

FIG. 1 illustrates a sectional view of a semiconductor package 100 according to an embodiment of the present disclosure.

First, as shown in FIG. 1, the semiconductor package 100 according to an embodiment of the present disclosure may include a first resin material 20 including an alignment groove 20a formed therein; a semiconductor chip 30 inserted into and aligned in the alignment groove 20a; a post 40 formed on the semiconductor chip 30; a second resin material 50 surrounding the post 40 and the semiconductor chip 30; a redistribution layer 60 electrically connected to the posts 40 and formed on the second resin material 50; an insulating films 70 serving to protect a portion of the redistribution layer 60; an under bump metal (UBM) 80 formed on the redistribution layers 60; and a solder ball 90 bonded to the UBM 80.

Here, the first resin material 20 may be formed in a shape of surrounding sides of the semiconductor chip 30, and the second resin material 50 may be formed on the first resin material 20 in a shape of surrounding portions of an upper surface of the semiconductor chip 30 and sides of the post 40.

Accordingly, the alignment groove 20a may be first formed in the first resin material 20 such that the semiconductor chip 30 is aligned therein, and the second resin material 50 may be secondarily formed to fix the aligned semiconductor chip 30.

Therefore, since the first resin material 20 is previously aligned in the semiconductor chip 30, the semiconductor chip 30 may be prevented from being moved out of a correct position thereof by flow of a molten second resin material in a process of molding the second resin material 50, so that the semiconductor chip 30 is fixed at a correct position.

Here, the first resin material 20 and the second resin material 50 may be made of the same material, and a molding time and temperature may be precisely controlled such that the first resin material 20 is not completely melted due to the molten second resin material 50.

In addition, the first resin material 20 may be made of a material having a high melting point, and the second resin material 50 may be made of a material having a low melting point, so that the first resin material 20 is prevented from being melted by the molten second resin material 50.

FIGS. 2 to 9 are sectional views illustrating a process of fabricating the semiconductor package 100 of FIG. 1 step by step.

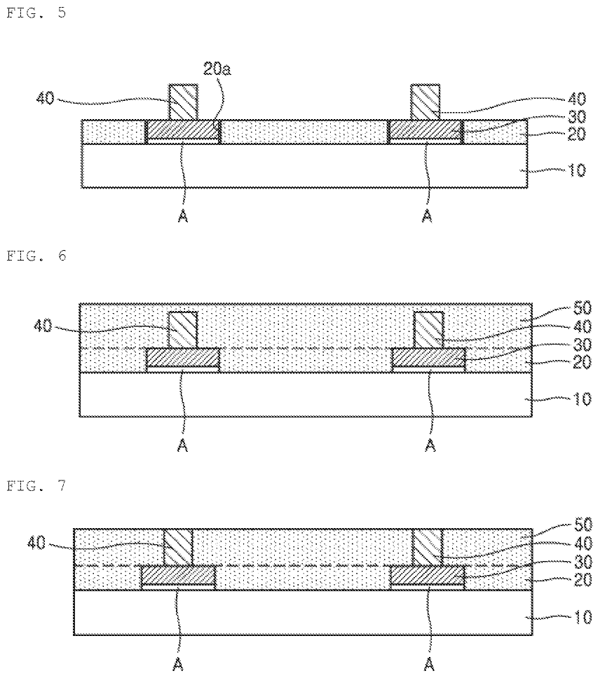

Each step of a process of fabricating the semiconductor package 100 of FIG. 1 is described with reference to FIGS. 2 to 9. First, as shown in FIG. 2, a carrier substrate 10 is prepared. As shown in FIG. 3, a first resin material 20 is printed or molded on the carrier substrate 10. As shown in FIG. 4, portions of the first resin material 20 are removed to form alignment grooves 20a on the carrier substrate 10.

Here, the alignment grooves 20a may serve as guides for guiding semiconductor chips 30 to correct positions, when the semiconductor chips 30 are mounted, such that the semiconductor chips 30 described below are aligned at correct positions.

Accordingly, the first resin material 20, in which the alignment grooves 20a are formed, may be formed on the carrier substrate 10.

Subsequently, as shown in FIG. 5, the semiconductor chips 30, to which posts 40 are respectively attached, may be respectively mounted in the alignment grooves 20a to be aligned at correct positions.

Here, as shown in FIG. 5, first, adhesive layers A may be respectively formed on lower surfaces of the semiconductor chips 30. The semiconductor chips 30 may be aligned in a face-up shape wherein the adhesive layers A on the lower surface of the semiconductor chips 30 are bonded to the carrier substrate 10 and upper surfaces of the semiconductor chips 30 are active surfaces.

Here, in terms of strength and durability, the sizes of the alignment grooves 20a in the first resin material 20 are preferably larger than those of the semiconductor chips and the thickness of the first resin material 20 is preferably thicker than those of the semiconductor chips 30, as shown in FIG. 5, such that the semiconductor chips 30 are inserted into the alignment grooves 20a and the second resin material 50 are formed on the semiconductor chips 30.

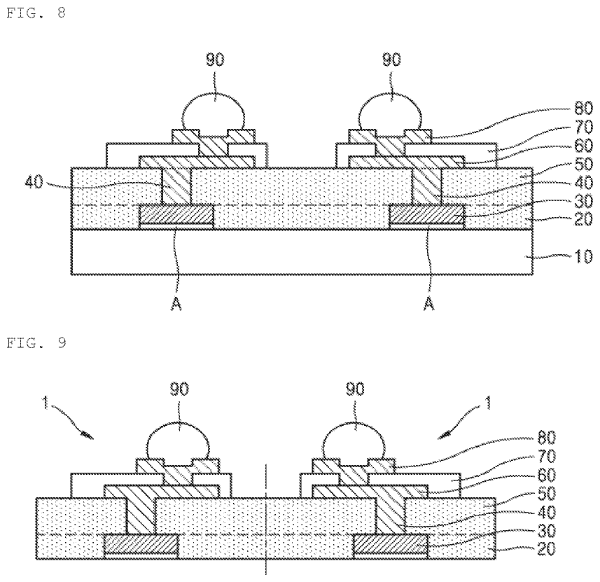

Subsequently, as shown in FIG. 6, the second resin material 50 may be formed on the carrier substrate 10, the semiconductor chips 30, and the posts 40.

Here, the second resin material 50 and the first resin material 20 are preferably made of substantially the same material to realize strong bonding between the first resin material 20 and the second resin material 50. However, the present disclosure is not limited thereto, and the second resin material 50 and the first resin material 20 may be made of different materials.

Subsequently, as shown in FIG. 7, a portion of the second resin material 50 may be ground (front ground) such that only portions of the posts 40 are exposed.

Subsequently, as shown in FIG. 8, redistribution layers 60 may be respectively formed on the exposed posts 40, insulating film patterns 70 or UBM patterns 80 may be respectively formed on the redistribution layers 60, and solder balls 90 may be respectively bonded onto the redistribution layers 60 or the UBM patterns 80.

Here, the insulating films 70 may be, for example, a passivation layer such as a polybenzoxazole (PBO) layer. In addition, polyimide (PI), benzo cyclo butene (BCB), bismaleimide triazine (BT), phenolic resin, epoxy, silicone, an oxide film (SiO₂), a nitride film (Si₃N₄) and equivalents thereof may be used as the insulating film 70.

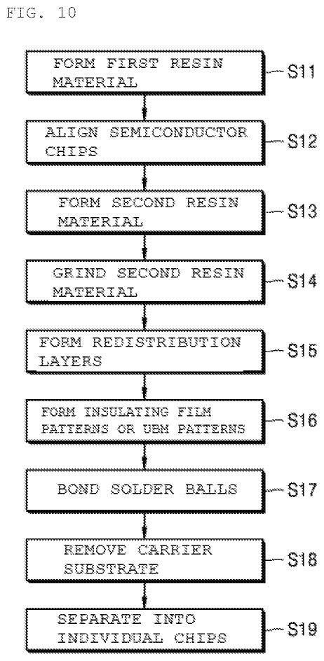

Subsequently, as shown in FIG. 9, the carrier substrate 10 may be removed from the first resin material 20 and the semiconductor chips 30, and then the first resin material 20 and the second resin material 50 may be sawed to separate into individual chips 1.

Here, since the carrier substrate 10 is made of a light-transmitting material such as a UV-transmitting material, or a thermally conductive material, and the adhesive layers A are made of a photoplastic material such as a UV-plastic material, or a thermoplastic material, the carrier substrate 10 may be easily separated by irradiating with UV light, etc., or heating.

Accordingly, the semiconductor package 100 fabricated according to the above processes corresponds to a fan-out wafer-level package. In accordance with the present disclosure, separation of semiconductor chips occurring in a process of molding a resin material of the fan-out wafer-level package may be prevented.

FIG. 10 is a flowchart illustrating a method of fabricating the semiconductor package 100 of FIG. 1.

As shown in FIGS. 1 to 10, a method of fabricating the semiconductor package 100 of FIG. 1 may include a step (S11) of forming a first resin material 20, in which alignment grooves 20a are formed, on a carrier substrate 10; a step (S12) of respectively aligning semiconductor chips 30, to which posts 40 are respectively attached, in the alignment grooves 20a; a step (S13) of forming a second resin material 50 on the carrier substrate 10, the semiconductor chips 30, and the posts 40; a step (S14) of grinding a portion of the second resin material 50 such that portions of the posts 40 are exposed; a step (S15) of respectively forming redistribution layers 60 on the exposed posts 40; a step (S16) of respectively forming insulating film patterns 70 or UBM patterns 80 on the redistribution layers 60; a step (S17) of respectively bonding solder balls 90 onto the redistribution layers 60 or the UBM patterns 80; a step (S18) of removing the carrier substrate 10 from the first resin material 20 and the semiconductor chips 30; and a step (S19) of sawing the first resin material 20 and the second resin material 50 to separate into individual chips 1.

Here, the step (S12) of respectively aligning semiconductor chips 30 having posts 40 respectively attached thereto to the alignment grooves 20a may include a step of respectively forming the adhesive layers A on lower surfaces of the semiconductor chips 30; and a step of aligning the semiconductor chips 30 in a face-up shape wherein the adhesive layers A on lower surfaces of the semiconductor chips 30 are bonded to the carrier substrate 10 and upper surfaces of the semiconductor chips 30 are active surfaces.

FIG. 11 is a flowchart illustrating an embodiment of the method of fabricating the semiconductor package 100 of FIG. 10.

As shown in FIGS. 1 to 11, the step (S11) of forming a first resin material 20 having alignment grooves 20a therein on a carrier substrate 10 may include a step (S111) of printing or molding the first resin material 20 on the carrier substrate 10; and a step (S112) of removing portions of the first resin material 20 to form the alignment grooves 20a on the carrier substrate 10.

Here, the step (S112) of removing portions of the first resin material 20 to form the alignment grooves 20a on the carrier substrate 10 may include a step of processing the first resin material 20 using one or more selected from among etching, sawing, drilling, laser drilling, through mold via (TMV) processing, and a combination thereof such that portions of the carrier substrate 10 are exposed.

However, the step (S11) is not limited to the process, and may be carried out by various methods.

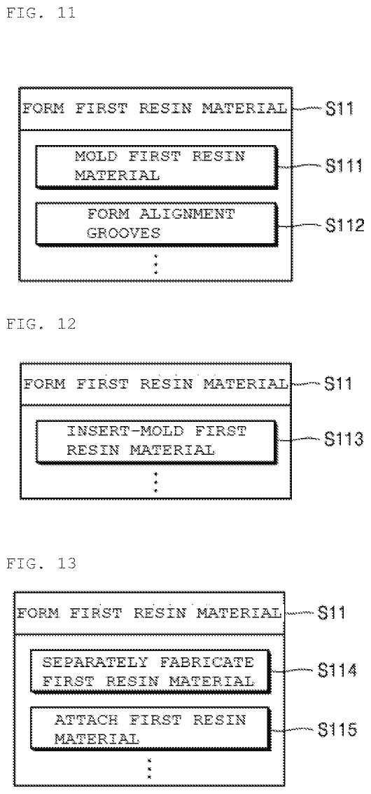

FIG. 12 is a flowchart illustrating another embodiment of the method of fabricating the semiconductor package 100 of FIG. 10.

For example, as shown in FIG. 12, the step (S11) of forming the first resin material 20 having the alignment grooves 20a therein on the carrier substrate 10 may include a step (S113) of inserting the carrier substrate 10 into an insert mold to form cavities and insert-molding the first resin material 20 around the cavities, so as to form the alignment grooves 20a in the first resin material 20.

FIG. 13 is a flowchart illustrating still another embodiment of the method of fabricating the semiconductor package 100 of FIG. 10.

For example, as shown in FIG. 13, the step (S11) of forming the first resin material 20, in which the alignment grooves 20a are formed, on the carrier substrate 10 may include a step (S114) of separately fabricating the first resin material 20, in which the alignment grooves 20a are formed, using a mold; and a step (S115) of attaching the first resin material 20 to the carrier substrate 10.

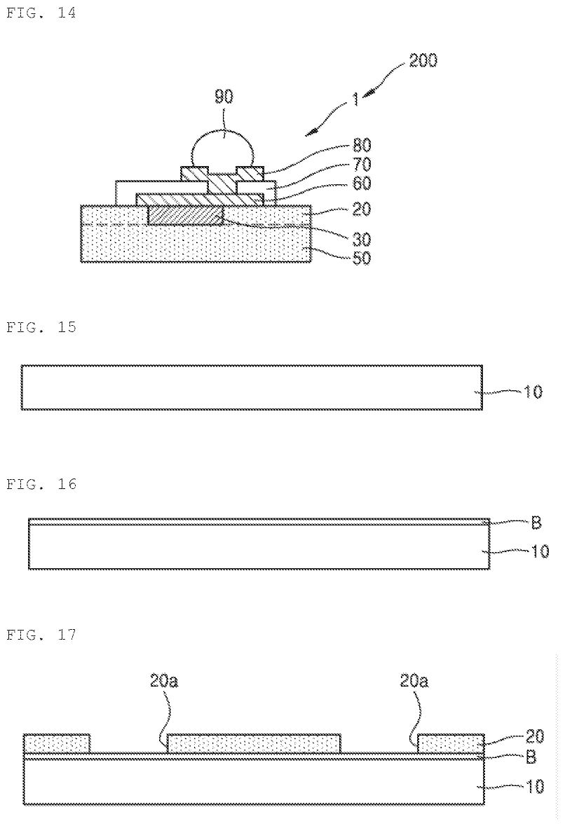

FIG. 14 illustrates a sectional view of a semiconductor package 200 according to another embodiment of the present disclosure.

First, as shown in FIG. 14, the semiconductor package 200 according to an embodiment of the present disclosure may include a first resin material 20 including an alignment groove 20a formed therein; a semiconductor chip 30 inserted into and aligned in the alignment groove 20a; a second resin material 50 surrounding the semiconductor chip 30; a redistribution layer 60 electrically connected to the semiconductor chip 30 and formed on the second resin material 50; an insulating films 70 serving to protect a portion of the redistribution layer 60; an under bump metal (UBM) 80 formed on the redistribution layers 60; and a solder ball 90 bonded to the UBM 80.

Here, the first resin material 20 may be formed in a shape of surrounding sides of the semiconductor chip 30, and the second resin material 50 may be formed on the first resin material 20 in a shape of surrounding a lower surface of the semiconductor chip 30.

Accordingly, the alignment groove 20a may be first formed in the first resin material 20 such that the semiconductor chip 30 is aligned therein, and the second resin material 50 may be secondarily formed to fix the aligned semiconductor chip 30.

Therefore, since the first resin material 20 is previously aligned in the semiconductor chip 30, the semiconductor chip 30 may be prevented from being moved out of a correct position thereof by flow of a molten second resin material in a process of molding the second resin material 50, so that the semiconductor chip 30 is fixed at a correct position.

FIGS. 15 to 21 are sectional views illustrating a process of fabricating the semiconductor package 200 of FIG. 14 step by step.

Each step of a process of fabricating the semiconductor package 200 of the FIG. 14 is described with reference to FIGS. 15 to 21. First, as shown in FIG. 15, a carrier substrate 10 is prepared. As shown in FIG. 16, a temporary adhesive layer B may be formed on the carrier substrate 10.

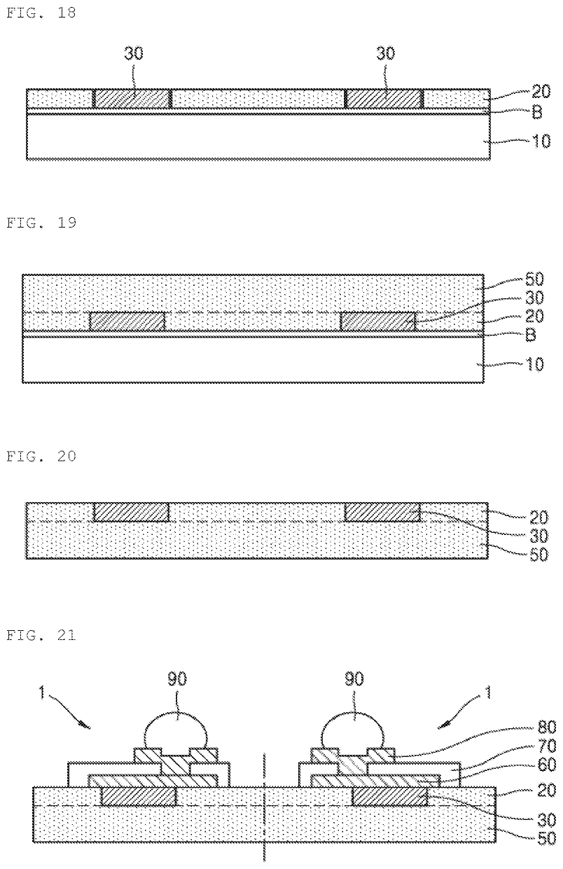

Subsequently, as shown in FIG. 17, the first resin material 20 having the alignment grooves 20a formed therein may be formed on the temporary adhesive layer B.

Here, the first resin material 20 may be formed by various method as shown in FIGS. 11 to 13. Thus, a detailed description thereof is omitted.

Subsequently, as shown in FIG. 18, semiconductor chips 30 may be aligned in the alignment grooves 20a.

Here, the semiconductor chips 30 may be aligned in a face-down shape wherein lower surfaces of the semiconductor chips 30 are active surfaces.

Subsequently, as shown in FIG. 19, a second resin material 50 may be formed on the carrier substrate 10 and the semiconductor chips 30.

Here, to exhibit higher strength and durability, the second resin material 50 and the first resin material 20 may be made of substantially the same material. However, the present disclosure is not limited thereto, and the second resin material 50 and the first resin material 20 may be made of different materials.

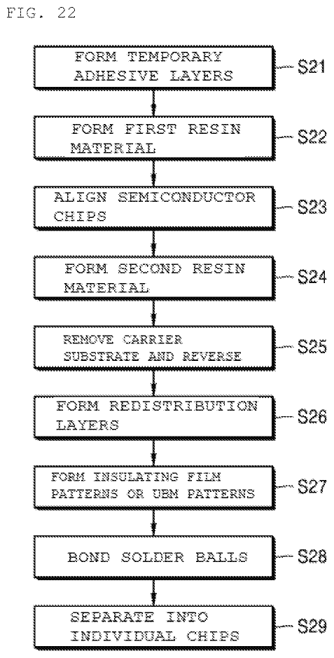

Subsequently, as shown in FIG. 20, the temporary adhesive layer B and the carrier substrate 10 may be removed from the semiconductor chips 30 and the second resin material 50, and the semiconductor chips 30 and the second resin material 50 may be reversed such that the semiconductor chips 30 are exposed upward.

Here, since the carrier substrate 10 is made of a light-transmitting material such as a UV-transmitting material, or a thermally conductive material, and the temporary adhesive layer B may be made of a photoplastic material such as a UV-plastic material, or a thermoplastic material, the carrier substrate 10 may be easily separated by irradiating with UV light, etc., or heating.

Subsequently, as shown in FIG. 21, redistribution layers 60 may be respectively formed on the exposed the semiconductor chips 30, insulating film patterns 70 or UBM patterns 80 may be respectively formed on the redistribution layers 60, and solder balls 90 may be respectively bonded onto the redistribution layers 60 or the UBM patterns 80. Next, the first resin material 20 and the second resin material 50 are sawed along a cut line (an alternate long and short dash line of FIG. 21) thereof, thereby being separated into individual chips 1.

FIG. 22 is a flowchart illustrating a method of fabricating the semiconductor package 200 of FIG. 14.

As shown in FIGS. 14 to 22, a method of fabricating the semiconductor package 200 of FIG. 14 may include a step (S21) of forming a temporary adhesive layer B on a carrier substrate 10; a step (S22) of forming a first resin material 20, in which alignment grooves 20a are formed, on the temporary adhesive layer B; a step (S23) of respectively aligning semiconductor chips 30 in the alignment grooves 20a; a step (S24) of forming a second resin material 50 on the carrier substrate 10 and the semiconductor chips 30; a step (S25) of removing the temporary adhesive layer B and the carrier substrate 10 from the semiconductor chips 30 and the second resin material 50, and reversing the semiconductor chips 30 and the second resin material 50 such that the semiconductor chips 30 are exposed upward; a step (S26) of respectively forming redistribution layers 60 on the exposed semiconductor chips 30; a step (S27) of respectively forming insulating film patterns 70 or UBM patterns 80 on the redistribution layers 60; a step (S28) of respectively bonding solder balls 90 onto the redistribution layers 60 or the UBM patterns 80; and a step (S29) of sawing the first resin material 20 and the second resin material 50 to separate into individual chips 1.

Here, the step (S23) of respectively aligning the semiconductor chips 30 in the alignment grooves 20a may include a step of aligning the semiconductor chips 30 in a face-down shape wherein lower surfaces of the semiconductor chips 30 become active surfaces.

In addition, the step (S22) of forming the first resin material 20, in which the alignment grooves 20a are formed, on the temporary adhesive layer B may include a step of printing or molding the first resin material 20 on the temporary adhesive layer B; and a step of removing portions of the first resin material 20 to form the alignment grooves 20a on the temporary adhesive layer B.

In addition, the step of removing portions of the first resin material 20 to form the alignment grooves 20a on the temporary adhesive layer B may include a step of processing the first resin material 20 using one or more selected from among etching, sawing, drilling, laser drilling, through mold via (TMV) processing, and a combination thereof such that portions of the temporary adhesive layer B are exposed.

In addition, the step (S22) of forming the first resin material 20, in which the alignment grooves 20a are formed, on the temporary adhesive layer B may include a step of inserting the temporary adhesive layer B and the carrier substrate 10 into an insert mold to form cavities and insert-molding the first resin material 20 around the cavities so as to form the alignment grooves 20a in the first resin material 20.

In addition, the step (S22) of forming the first resin material 20, in which the alignment grooves 20a are formed, on the temporary adhesive layer B may include a step of separately fabricating the first resin material 20, in which the alignment grooves 20a are formed, using a mold; and a step of attaching the first resin material 20 to the temporary adhesive layer B.

In addition, the semiconductor package 200 may be a fan-out wafer-level package.

In addition, the step (S22) of forming the first resin material 20, in which the alignment grooves 20a are formed, on the temporary adhesive layer B may include a step of forming the alignment grooves 20a in the first resin material 20 to be larger than the semiconductor chips 30 and forming the first resin material 20 to be thicker than the semiconductor chips 30.

In addition, the step (S24) of forming the second resin material 50 on the carrier substrate 10 and the semiconductor chips 30 may include a step of forming the second resin material 50 with substantially the same material as the first resin material 20.

As apparent from the above description, the present disclosure provides a method of fabricating a semiconductor package which is capable of preventing the separation of a semiconductor chip occurring in a process of molding a resin material of a fan-out wafer-level package. However, the scope of the present disclosure is not limited to the effects.

While the present disclosure has been particularly shown and described with reference to exemplary embodiments thereof, it will be understood by those of ordinary skill in the art that various changes in form and details may be made therein without departing from the spirit and scope of the present disclosure. Therefore, the true technical protection scope of the present disclosure should be defined by the technical spirit of the appended claims.

What is claimed is:

1. A method of fabricating a semiconductor package, the method comprising:
forming a first resin material, in which alignment grooves are formed, on a carrier substrate;
respectively aligning semiconductor chips, to which posts are respectively attached, in the alignment grooves;
forming a second resin material on the carrier substrate, the semiconductor chips, and the posts;
grinding a portion of the second resin material such that portions of the posts are exposed;
respectively forming redistribution layers on the exposed posts;
respectively forming insulating film patterns or UBM patterns on the redistribution layers;
respectively bonding solder balls onto the redistribution layers or the UBM patterns;
removing the carrier substrate from the first resin material and the semiconductor chips; and
sawing the first resin material and the second resin material to separate into individual chips.

2. The method according to claim 1, wherein the respectively aligning comprises:
respectively forming the adhesive layers on lower surfaces of the semiconductor chips; and
aligning the semiconductor chips in a face-up shape wherein the adhesive layers on lower surfaces of the semiconductor chips are bonded to the carrier substrate and upper surfaces of the semiconductor chips are active surfaces.

3. The method according to claim 1, wherein the forming of the first resin material comprises:
printing or molding the first resin material on the carrier substrate; and
removing portions of the first resin material to form the alignment grooves on the carrier substrate.

4. The method according to claim 3, wherein the removing comprises processing the first resin material using one or more selected from among etching, sawing, drilling, laser drilling, through mold via (TMV) processing, and a combination thereof such that portions of the carrier substrate are exposed.

5. The method according to claim 1, wherein the forming of the first resin material comprises inserting the carrier substrate into an insert mold to form cavities and insert-molding the first resin material around the cavities, so as to form the alignment grooves in the first resin material.

6. The method according to claim 1, wherein the forming of the first resin material comprises:
separately fabricating the first resin material, in which the alignment grooves are formed, using a mold; and
attaching the first resin material to the carrier substrate.

7. The method according to claim 1, wherein the semiconductor package is a fan-out wafer-level package.

8. The method according to claim 1, wherein the forming of the first resin material comprises forming the alignment grooves in the first resin material to be larger than the semiconductor chips and forming the first resin material to be thicker than the semiconductor chips.

9. The method according to claim 1, wherein the forming of the second resin material comprises forming the second resin material with substantially the same material as the first resin material.

10. A method of fabricating a semiconductor package, the method comprising:
forming a temporary adhesive layer on a carrier substrate;
forming a first resin material, in which alignment grooves are formed, on the temporary adhesive layer;
respectively aligning semiconductor chips in the alignment grooves;
forming a second resin material on the carrier substrate and the semiconductor chips;
removing the temporary adhesive layer and the carrier substrate from the semiconductor chips and the second resin material, and reversing the semiconductor chips and the second resin material such that the semiconductor chips are exposed upward;
respectively forming redistribution layers on the exposed semiconductor chips;
respectively forming insulating film patterns or UBM patterns on the redistribution layers;
respectively bonding solder balls onto the redistribution layers or the UBM patterns; and
sawing the first resin material and the second resin material to separate into individual chips.

11. The method according to claim 10, wherein the respectively aligning comprises aligning the semiconductor chips in a face-down shape wherein lower surfaces of the semiconductor chips become active surfaces.

12. The method according to claim 10, wherein the forming of the first resin material comprises:
printing or molding the first resin material on the temporary adhesive layer; and
removing portions of the first resin material to form the alignment grooves on the temporary adhesive layer.

13. The method according to claim 12, wherein the removing comprises processing the first resin material using one or more selected from among etching, sawing, drilling, laser drilling, through mold via (TMV) processing, and a combination thereof such that portions of the temporary adhesive layer are exposed.

14. The method according to claim 10, wherein the forming of the first resin material comprises inserting the temporary adhesive layer and the carrier substrate into an insert mold to form cavities and insert-molding the first resin material around the cavities, so as to form the alignment grooves in the first resin material.

15. The method according to claim 10, wherein the forming of the first resin material comprises:
separately fabricating the first resin material, in which the alignment grooves are formed, using a mold; and
attaching the first resin material to the temporary adhesive layer.

16. The method according to claim 10, wherein the semiconductor package is a fan-out wafer-level package.

17. The method according to claim 10, wherein the forming of the first resin material comprises forming the alignment grooves in the first resin material to be larger than the semiconductor chips and forming the first resin material to be thicker than the semiconductor chips.

18. The method according to claim 10, wherein the forming of the second resin material comprises forming the second resin material with substantially the same material as the first resin material.
